(19) United States
(12) Patent Application Publication
(10) Pub. No.: US 2012/0241209 A1
(43) Pub. Date: Sep. 27, 2012

(54) WAFER-LEVEL ELECTROMAGNETIC INTERFERENCE SHIELDING STRUCTURE AND MANUFACTURING METHOD THEREOF

(75) Inventor: MING-CHE WU, NANTOU COUNTY (TW)

(73) Assignees: UNIVERSAL GLOBAL SCIENTIFIC INDUSTRIAL CO., LTD., Nantou County (TW); UNIVERSAL SCIENTIFIC INDUSTRIAL(SHANGHAI) CO., LTD., Shanghai (CN)

(21) Appl. No.: 13/207,534

(22) Filed: Aug. 11, 2011

(30) Foreign Application Priority Data
Mar. 23, 2011 (TW) 100109930

(51) Int. Cl. H05K 9/00; H05K 3/10

(52) U.S. Cl. 174/350; 29/846

(57) ABSTRACT

A wafer-level electromagnetic interference (EMI) shielding structure, which includes: a wafer, an exposed circuit unit, and an EMI shielding unit. The exposed circuit unit is disposed on the top surface of the wafer. At least one conductor is disposed on the exposed circuit unit. The EMI shielding unit has a first EMI shielding layer set around the surrounding surface of the wafer, and a second EMI shielding layer coated to the bottom surface of the wafer. Based on the wafer-level manufacturing process of the instant disclosure, the EMI shielding structure is miniaturized, and each individual wafer is protected against the EMI effect.

### BACKGROUND OF THE INVENTION

1. Field of the Invention

The present invention relates to an electromagnetic interference (EMI) shielding structure; in particular, to a wafer-level EMI shielding structure and manufacturing method thereof.

2. Description of Related Art

The primary purpose of EMI shielding structure is to prevent the effect of electromagnetic interference from occurring between each electronic circuit components, and structural wise is primarily formed from combination of substrate unit, electronic circuit unit, metallic shielding unit, and electrical coupling unit. Electronic circuit components with EMI shielding structure can be widely applied to all kinds of everyday products, such as applications of notebook computers, mobile phones, e-book readers, electronic tablets, electronic gaming console, communication products, digital photo frames, mobile navigation systems, and digital televisions.

Manufacturing technologies related to EMI shielding structures uses substrate and electronic circuit components for various kinds of electrical coupling, so that the overall physical structure is large, or the final product becomes overly thick, which goes counter to the modern trend of thinner and smaller electronic products. Therefore, research on thinner and smaller EMI shielding structure is the foremost goal for the present improvement of EMI shielding structure.

### SUMMARY OF THE INVENTION

The object of the present invention is to provide a wafer-level EMI shielding structure and manufacturing method thereof with EMI shielding effect.

In order to achieve the aforementioned objects, according to an embodiment of the present invention, a wafer-level EMI shielding structure is provided, which includes: a wafer and an EMI shielding unit. The top surface of the wafer is disposed with an exposed circuit unit, and at least one conductor is disposed on the exposed circuit unit. The EMI shielding unit includes a first EMI shielding layer set around the surrounding surface of the wafer, and a second EMI shielding layer coated to the bottom surface of the wafer. The first shielding layer and the second shielding layer are mutually connected, such that the two are electrically coupled.

Per aforementioned, the wafer-level EMI shielding structure provided by an embodiment of the present invention has the effect of miniaturizing EMI shielding structure. By utilizing wafer-level manufacturing method, and utilizing the first shielding layer and the second shielding layer respectively located at the surrounding surface of the wafer and the bottom of the wafer, the EMI shielding unit is formed, and thereby both the wafer and the exposed circuit unit both possess effect of EMI interference prevention.

In order to further the understanding regarding the present invention, the following embodiments are provided along with illustrations to facilitate the disclosure of the present invention.

### BRIEF DESCRIPTION OF THE DRAWINGS

FIG. 1 shows a cross-sectional view of a wafer-level electromagnetic interference (EMI) shielding structure according to an embodiment of the present invention;

FIG. 2A shows a cross-sectional view of a wafer-level EMI shielding structure according to the first step of an embodiment of the present invention;

FIG. 2B shows a cross-sectional view of a wafer-level EMI shielding structure according to the second step of the embodiment of the present invention;

FIG. 2C shows a cross-sectional view of a wafer-level EMI shielding structure according to the third step of the embodiment of the present invention;

FIG. 2D shows a cross-sectional view of a wafer-level EMI shielding structure according to the fourth step of the embodiment of the present invention;

FIG. 2E shows a cross-sectional view of a wafer-level EMI shielding structure according to the fifth step of the embodiment of the present invention;

FIG. 2F shows a cross-sectional view of a wafer-level EMI shielding structure according to the sixth step of the embodiment of the present invention;

FIG. 2G shows a cross-sectional view of a wafer-level EMI shielding structure according to the seventh step of the embodiment of the present invention;

FIG. 3 shows a top view of the wafer-level EMI shielding structure in FIG. 2B.

FIG. 4 shows a flow chart diagram of a wafer-level EMI shielding structure manufacturing method according to the present invention.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

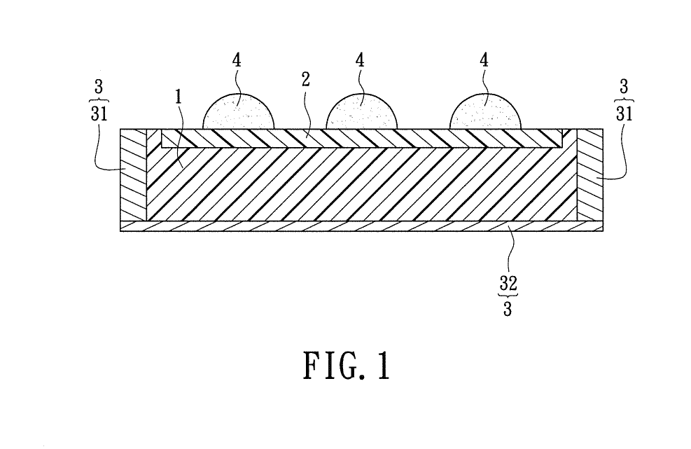

Reference FIG. 1, which shows a cross-sectional view of a wafer-level electromagnetic interference (EMI) shielding structure according to an embodiment of the present invention. The wafer-level EMI shielding structure according to an embodiment of the present invention includes: a wafer 1, an exposed circuit unit 2, and an EMI shielding unit 3.

The wafer 1 can be made from a silicon wafer substrate material. The top surface of the wafer 1 is disposed with the exposed circuit unit 2, and at least one conductor 4 is disposed on the exposed circuit unit 2. Also, the conductor 4 can be a solder ball or other conducting bump (such as metallic bump), so as to ensure possession of excellent conduction characteristic. The exposed circuit unit 2 can be an exposed integrated circuit, but is not limited thereby.

The EMI shielding unit 3 is formed from two EMI shielding layers, respectively being a first EMI shielding layer 31 and a second EMI shielding layer 32. The first EMI shielding layer 31 is set around the surrounding surface of the wafer 1, which means, the first EMI shielding layer 31 surrounds the lateral surface of the wafer 1. The second EMI shielding layer 32 covers the bottom surface of the wafer 1, and is connected to the first EMI shielding layer 31. In other words, the second EMI shielding layer 32 is on a different plane level as the first EMI shielding layer 31, and the two has a right angle relation. Furthermore, the first EMI shielding layer 31 and the second EMI shielding layer 32 are mutually connected, such that the two are electrically coupled. Additionally, the second EMI shielding layer 32 can be a metallic sputtering layer, wherein copper would be an especially ideal choice. The first EMI shielding layer 31 is of metallic material, also with copper as an ideal choice.

If adequate EMI shielding effect is to be achieved, then the overall structure must have grounding characteristic. Therefore, the EMI shielding unit 3 needs to be electrically coupled with the grounding portion of the wafer 1. The aforementioned grounding portion is located at the lateral surface of the wafer 1, which is also the surrounding surface of the wafer 1. In other words, when the first EMI shielding layer 31 is in contact with the surrounding surface of the wafer 1, then the two forms electrical coupling relation. Through the aforementioned electrical coupling relation, the EMI shielding unit 3 can achieve the best EMI shielding effect.

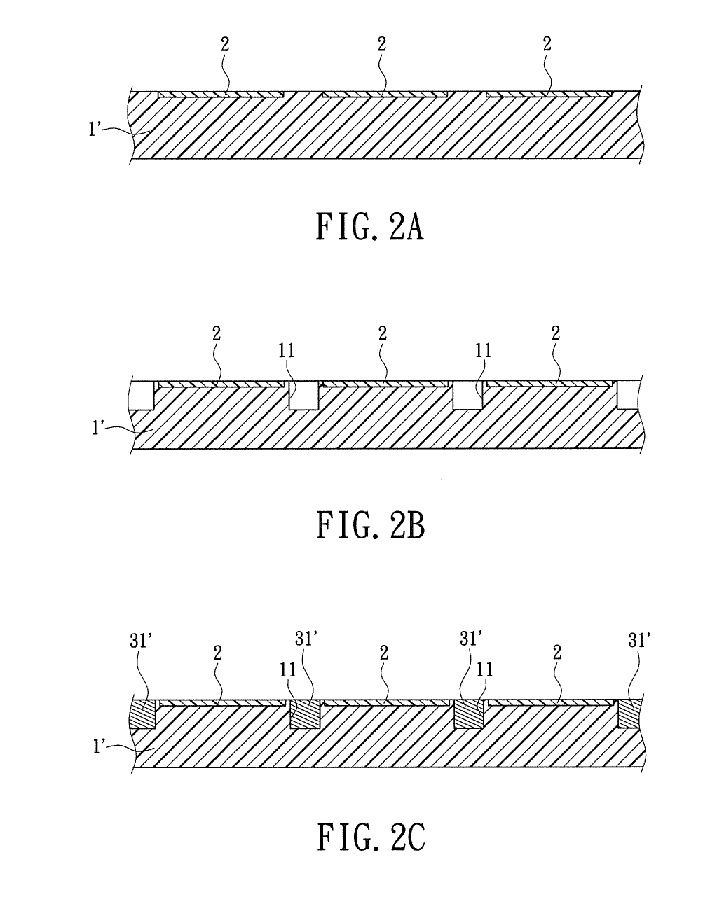

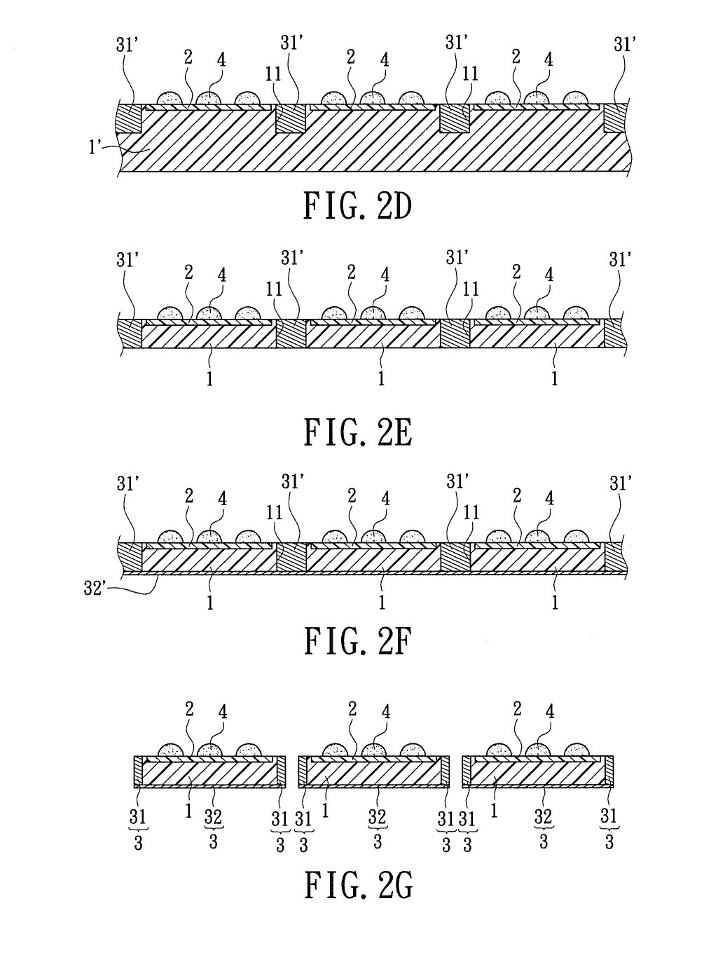

Reference FIG. 2A to 2G; which respectively show a cross-sectional view of a wafer-level EMI shielding structure according to the first to seventh steps of an embodiment of the present invention manufacturing method. According to the present invention wafer-level EMI shielding structure manufacturing method, the steps include:

Step 1 (see FIG. 2A), first; provide a wafer substrate 1′, wherein the top surface of the wafer substrate 1′ has a plurality of exposed circuit units 2. Of course, the top surface of the wafer substrate 1′ can also have just at least one exposed circuit unit 2. Therefore, the number of the exposed circuit unit 2 for the present invention can be determined by design requirement.

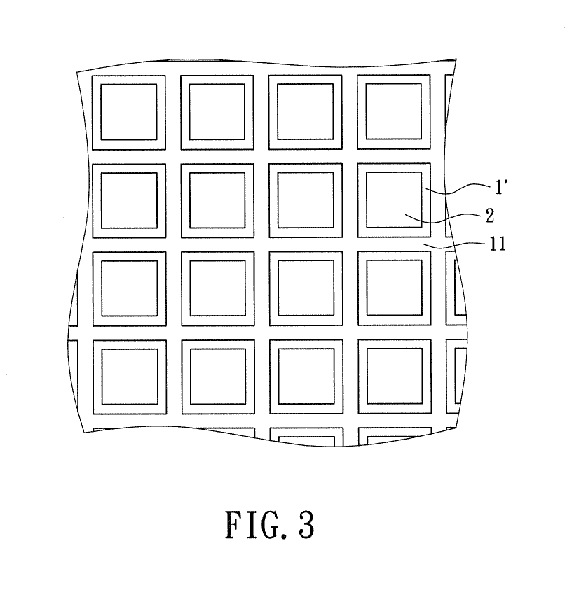

Step 2 (see FIG. 2B), form a plurality line of grooves 11 on the top surface of the wafer substrate 1′, wherein each line of groove 11 is positioned between two of the exposed circuit units 2. In other words, if the exposed circuit unit 2 is formed in an array formation on the wafer substrate 1′, then the plurality line of grooves 11 is presented in a chessboard crisscross displacement on the wafer substrate 1′ (reference FIG. 3, which is a top view of FIG. 2B, so as to further understand the displacement of the plurality line of grooves 11 of the present step). Of course, the number of line of grooves 11 on the top surface of the wafer substrate 1′ can also be at least one line. Therefore, the line number of the groove 11 of the present invention can be determined by design requirement.

Step 3 (see FIG. 2C), form a first conducting material 31′ within the plurality line of grooves 11. In other words, fill the first conducting material 31′ into all the plurality line of grooves 11.

Step 4 (see FIG. 2D), form at least one conductor 4 on the top surface of each of the exposed circuit units 2, and the conductors 4 are respectively electrically coupled to the exposed circuit units 2. Therein, the aforementioned conductors 4 can be solder balls or other conducting bumps (such as metallic bumps).

Step 5 (see FIG. 2E), by thinning the bottom surface of the wafer substrate 1′, so that a plurality of wafers 1 is formed and so that the first conducting material 31′ is exposed at the bottom, wherein the wafers 1 are respectively separated for a set distance and respectively corresponds to the plurality of exposed circuit units 2. The aforementioned method of thinning the bottom surface of the wafer substrate 1′ can be grinding. In other words, through grinding, the thickness of the wafer substrate 1′ can be made thin, so that the bottom of the first conducting material 31′ is exposed. Thereby, the wafer substrate 1′ is separated by the first conducting material 31′ into areas equal in number to the exposed circuit units 2, and each area is an independent wafer 1.

Step 6 (see FIG. 2F), simultaneously disposing a second conducting material 32′ over the bottom of each of the wafers 1 and the bottoms of the first conducting materials 31′. Therein the second conducting material 32′ can be formed via sputtering or other methods.

Step 7 (see FIG. 2G), cut the first conducting material 31′ and the second conducting material 32′ along the plurality line of grooves 11, so as to form a plurality of wafer-level EMI shielding structures. At this step, the wafer-level EMI shielding structure of the present invention is complete.

Through the aforementioned cutting step, the first conducting material 31′ is segmented into a plurality of first EMI shielding layers 31, and the second conducting material 32′ is segmented into a plurality of second shielding layers 32. Therein the first EMI shielding layers 31 and the second EMI shielding layers 32 forms a plurality of EMI shielding units 3 for preventing the exposed circuit units 2 from having EMI effect with surrounding environment. Additionally, the EMI shielding unit 3 and the grounding portion of the wafer 1 are electrically coupled through direct connection. For the present invention, the material of choice for each component that satisfies conduction characteristic and economic consideration is pure copper or copper alloy, but the present invention is not limited thereby, the material may also be other metallic material with good conducting characteristic. Therefore, the first EMI shielding layer 31 and the second EMI shielding layer 32 can be formed via copper metallic material.

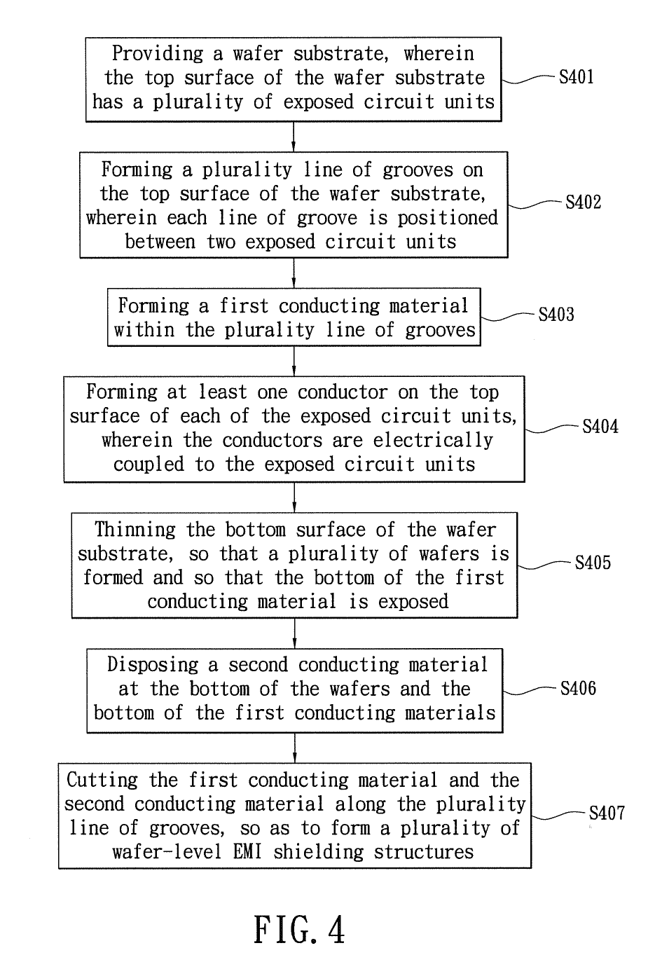

Reference FIG. 4, which shows a flow chart diagram of a wafer-level EMI shielding structure manufacturing method according to the present invention. Steps S401 to S407 respectively represents the first step to seventh step from an embodiment of the present invention. One can better understand the overall manufacturing method of the present invention via FIG. 4.

### Possible Effects of the Embodiments

According to the embodiments of the present invention, the aforementioned wafer-level EMI shielding structure utilizes wafer-level manufacturing method, so that the EMI shielding structure possesses miniaturizing effect. Furthermore by utilizing and respectively displacing the first EMI shielding layer and the second EMI shielding layer on the surrounding surface of the wafer and the bottom surface of the wafer, the EMI shielding unit is formed, thereby the wafer and the exposed circuit unit each individually has the effect of EMI prevention.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A wafer-level electromagnetic interference (EMI) shielding structure, comprising:
a wafer, the top surface of the wafer is disposed with an exposed circuit unit, at least one conductor is disposed on the exposed circuit unit; and
an EMI shielding unit having a first EMI shielding layer and a second EMI shielding layer, the first EMI shielding layer being set around the surrounding surface of the wafer, and the second EMI shielding layer being coated to the bottom surface of the wafer and connected with the first EMI shielding layer.

2. The wafer-level EMI shielding structure according to claim 1, wherein the wafer is a silicon wafer and the conductor is a solder ball or a metallic bump.

3. The wafer-level EMI shielding structure according to claim 1, wherein the first EMI shielding layer is of metallic material and the second EMI shielding layer is a metallic sputtering layer.

4. A wafer-level electromagnetic interference (EMI) shielding structure manufacturing method, the steps comprising:
providing a wafer substrate having a plurality of exposed circuit units disposed thereon;
forming a plurality line of grooves on the top surface of the wafer substrate, wherein each line of groove is positioned between two of the exposed circuit units;
forming a first conducting material within each line of grooves;
forming at least one conductor on the top surface of each of the exposed circuit units;
thinning the bottom surface of the wafer substrate, so that a plurality of wafers are formed and so that the bottom of the first conducting material is exposed, wherein the wafers are respectively separated for a set distance and respectively correspond to the plurality of exposed circuit units;
disposing a second conducting material at the bottom of the wafers and the bottom of the first conducting materials; and
cutting the first conducting material and the second conducting material along the plurality line of grooves, so as to form a plurality of wafer-level EMI shielding structures.

5. The wafer-level EMI shielding structure manufacturing method according to claim 4, wherein the second conducting material is formed through sputtering.

6. The wafer-level EMI shielding structure manufacturing method according to claim 4, wherein the bottom surface of the wafer substrate is thinned via grinding.

7. The wafer-level EMI shielding structure manufacturing method according to claim 4, wherein the plurality of conductors are solder balls or metallic bumps.

8. The wafer-level EMI shielding structure manufacturing method according to claim 4, wherein in the cutting step, the first conducting material is segmented into a plurality of first EMI shielding layers, and the second conducting material is segmented into a plurality of second shielding layers.

9. The wafer-level EMI shielding structure manufacturing method according to claim 8, wherein each wafer-level EMI shielding structure comprises:
a wafer having an exposed circuit unit disposed thereon, at least one conductor being disposed on the exposed circuit unit; and
an EMI shielding unit having a first EMI shielding layer and a second EMI shielding layer, the first EMI shielding layer is set around the surrounding surface of the wafer, and the second EMI shielding layer is coated to the bottom surface of the wafer and connects with the first EMI shielding layer.

10. The wafer-level EMI shielding structure manufacturing method according to claim 9, wherein the first EMI shielding layer and the second EMI shielding layer are formed with metallic material.

11. The wafer-level EMI shielding structure manufacturing method according to claim 9, wherein the first EMI shielding layer and the second EMI shielding layer form an EMI shielding unit for preventing the wafer from having EMI effect with surrounding environment.
